(19) United States
(12) Patent Application Publication
(10) Pub. No.: US 2026/0038614 A1
(43) Pub. Date: Feb. 5, 2026

(54) ROW ERROR MONITORING FOR MEMORY SYSTEMS

(71) Applicant: Micron Technology, Inc., Boise, ID (US)

(72) Inventor: Sai Krishna Mylavarapu, Folsom, CA (US)

(21) Appl. No.: 19/272,432

(22) Filed: Jul. 17, 2025

Related U.S. Application Data
(60) Provisional application No. 63/677,292, filed on Jul. 30, 2024.

(51) Int. Cl. G11C 29/02; G11C 29/00; G11C 29/52

(52) U.S. Cl. CPC G11C 29/022; G11C 29/52; G11C 29/702

(57) ABSTRACT

Methods, systems, and devices for row error monitoring for memory systems are described. The method may include a system (e.g., a memory system, a host system coupled with a memory system) detecting one or more errors of a row of memory cells of a memory system based on reading the row of memory cells and allocating a counter of the memory system to tracking errors of the row of memory cells based on detecting the one or more errors of the row of memory cells. Additionally, the method may include the system adjusting a value of the allocated counter based on errors of the row of memory cells including the detected one or more errors and perform an operation associated with the row of memory cells based on the adjusted value of the allocated counter satisfying a threshold.

### CROSS REFERENCE

The present Application for Patent claims priority to U.S. Patent Application No. 63/677,292 by Mylavarapu, entitled “ROW ERROR MONITORING FOR MEMORY SYSTEMS,” filed Jul. 30, 2024, which is assigned to the assignee hereof, and which is expressly incorporated by reference in its entirety herein.

### TECHNICAL FIELD

The following relates to one or more systems for memory, including row error monitoring for memory systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports row error monitoring for memory systems in accordance with examples as disclosed herein.

FIG. 2 shows an example of a system that supports row error monitoring for memory systems in accordance with examples as disclosed herein.

FIG. 3 shows an example of a process that supports row error monitoring for memory systems in accordance with examples as disclosed herein.

FIG. 4 shows a block diagram of an electronic device that supports row error monitoring for memory systems in accordance with examples as disclosed herein.

FIG. 5 shows a flowchart illustrating a method or methods that support row error monitoring for memory systems in accordance with examples as disclosed herein.

### DETAILED DESCRIPTION

In some memory operations, a host system may transmit a read command to a memory system to obtain data stored by a row of memory cells of the memory system (e.g., of a memory device of the memory system). While performing a read operation on the row of memory cells, the memory system may experience a row failure. A row failure may occur if the memory system detects or experiences one or more errors (e.g., correctable errors, uncorrectable errors) in the data stored by the row of memory cells. Based on (e.g. in response to) detecting the row failure, the memory system may report the row failure to the host system and perform a row recovery operation (e.g., a post package repair (PPR)) on the row of memory cells. Row failures may cause a significant set of access operations (e.g., read operations) to fail, which may contribute to latency and reliability issues.

A row failure may not be instantaneous, and may be a result of an accumulation of errors over time. Thus, it may be possible, through health monitoring, to identify which rows of memory cells may be more susceptible to a row failure. As described herein, a system for memory operations may monitor the health of rows of memory cells and employ row repair operations on the rows of memory cells based on the health monitoring to reduce failures in access operations. In some examples, in response to detecting an error in a row of memory cells, a system (e.g., a memory system, a host system) may allocate a counter associated with (e.g., of, stored in) a shallow buffer of the system to tracking errors of the row of memory cells and adjust a value of the counter based on at least the detected error. For example, the system may increment the value of the counter by one if the detected error includes a single bit error.

Based on incrementing one or more of such counters, a system may compare the respective values of the counters to a threshold. If the value of a counter satisfies the threshold (e.g., is greater than the threshold, is equal to the threshold, is greater than or equal to the threshold), a row repair operation may be performed on the row of memory cells. Alternatively, if the value of the counter does not satisfy the threshold, the system may continue to monitor the row of memory cells for errors. The system may be configured to store multiple counters, each configured to track errors of a respective row of memory cells of the memory system. Additionally, or alternatively, an allocation of one or more counters may be dynamic. For example, if a row repair operation is performed on a row of memory cells, the system may deallocate a counter from tracking the errors of the row of memory cells and allocate the counter to tracking errors of a different row of memory cells of the memory system. However, in these and other examples, a quantity of such counters may be less than a quantity of rows of memory cells in the memory system, with such counters being allocated to rows of memory cells for which an error is experienced. Using the methods as described herein may allow the system to proactively repair failing rows thereby reducing a quantity of access operations to fail at the system, and such monitoring may be implemented with a more-efficient allocation of resources (e.g., counters) than if counters are maintained for each of (e.g., all of) the rows of memory cells of a memory system regardless of whether a given row is identified to experience an error.

In addition to applicability in memory systems as described herein, techniques for row error monitoring for memory systems may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing user access failures associated with row failures, which may improve access speeds and access reliability, among other benefits.

Features of the disclosure are illustrated and described in the context of systems and architectures. Features of the disclosure are further illustrated and described in the context of a flow diagram and flowcharts.

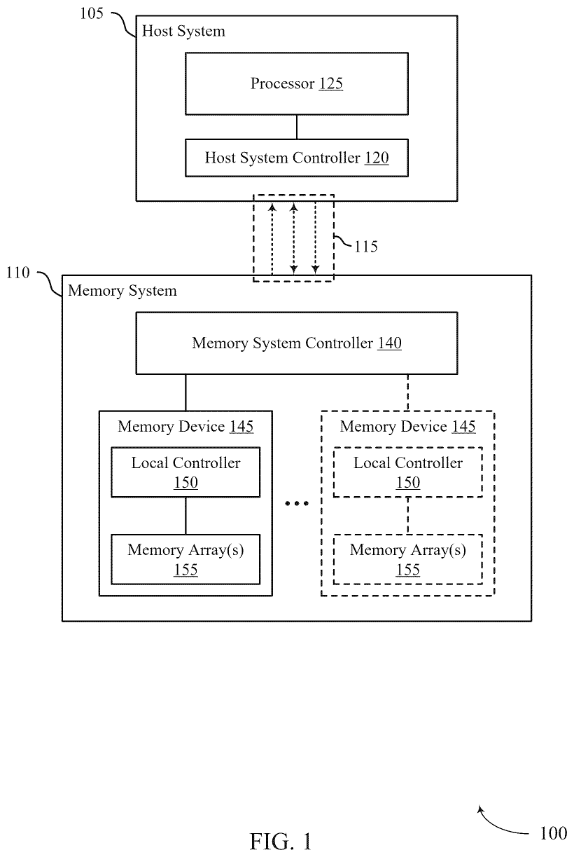

FIG. 1 illustrates an example of a system 100 that supports row error monitoring for memory systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some memory operations, a host system 105 may transmit a read command to a memory system 110 to obtain data stored by a row of memory cells (e.g., of a memory device 145, of a memory array 155). While performing a read operation on the row of memory cells, the memory system 110 may experience a row failure. A row failure may occur if the memory system 110 detects or experiences one or more errors (e.g., correctable errors, uncorrectable errors) in the data stored by the row of memory cells. In some implementations, based on (e.g. in response to) detecting the row failure (e.g., at the memory system 110, at the host system 105 based on data or another indication from the memory system 110), the memory system 110 may perform a row recovery operation (e.g., a post package repair (PPR)) on the row of memory cells. Row failures may cause a significant set of access operations (e.g., read operations) to fail, which may contribute to latency and reliability issues.

A row failure may not be instantaneous, and may be a result of an accumulation of errors over time. Thus, it may be possible, through health monitoring, to identify which rows of memory cells may be more susceptible to a row failure. As described herein, a memory system 110 or a host system 105 may monitor the health of rows of memory cells and employ row repair operations on the rows of memory cells based on the health monitoring to reduce failures in access operations. In some examples, in response to detecting an error in a row of memory cells, a system (e.g., a memory system 110, a host system 105) may allocate a counter associated with (e.g., of, stored in) a buffer of the system to tracking errors of the row of memory cells and adjust a value of the counter based on at least the detected error. For example, the system may increment the value of the counter by one if the detected error includes a single bit error.

Based on incrementing one or more of such counters, a system may compare the respective values of the counters to a threshold. If the value of a counter satisfies the threshold (e.g., is greater than the threshold, is equal to the threshold, is greater than or equal to the threshold), a row repair operation may be initiated on the row of memory cells. Alternatively, if the value of the counter does not satisfy the threshold, the system may continue to monitor the row of memory cells for errors. The system may be configured to store multiple counters, each configured to track errors of a respective row of memory cells of the memory system. Additionally, or alternatively, an allocation of one or more counters may be dynamic. For example, if a row repair operation is performed on a row of memory cells, the system may deallocate a counter from tracking the errors of the row of memory cells and allocate the counter to tracking errors of a different row of memory cells of the memory system. However, in these and other examples, a quantity of such counters may be less than a quantity of rows of memory cells in the memory system, with such counters being allocated to rows of memory cells for which an error is experienced. Using the methods as described herein may allow a system (e.g., a system 100, a memory system 110, a host system 105) to proactively repair failing rows thereby reducing a quantity of access operations to fail at the system, and such monitoring may be implemented with a more-efficient allocation of resources (e.g., counters) than if counters are maintained for each of (e.g., all of) the rows of memory cells of a memory system 110 regardless of whether a given row is identified to experience an error.

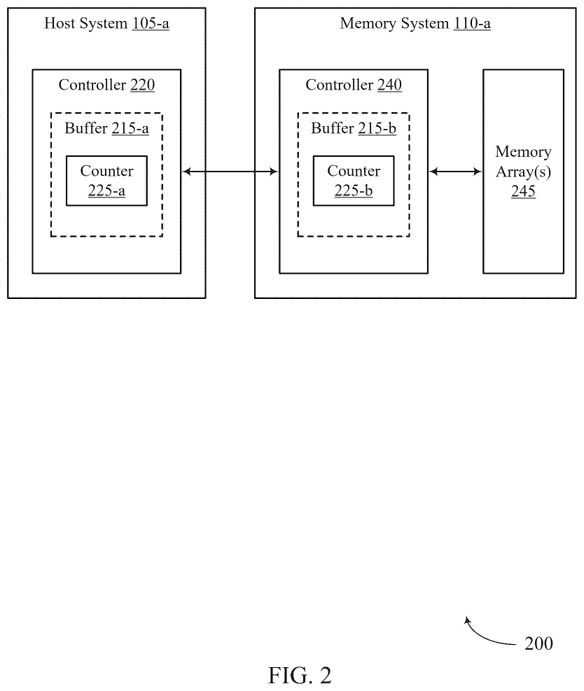

FIG. 2 shows an example of a system 200 that supports row error monitoring for memory systems in accordance with examples as disclosed herein. In some examples, the system 200 may implement aspects of a system 100. For example, the system 200 may include a host system 105-a and a memory system 110-a. The host system 105-a may include a controller 220, which may be an example of a host system controller 120. The memory system 110-a may include a controller 240 which may be an example of a memory system controller 140, or a local controller 150, or a combination thereof. The memory system 110-a may also include one or more memory arrays 245, which may be an example of one or more memory arrays 155 included in one or more memory devices 145 (e.g., one or more memory dies).

In some examples, the host system 105-a may transmit a read command to the memory system 110-a to read a row of memory cells of a memory array 245 of the memory system 110-a. Based on (e.g., in response to) receiving the read command, the memory system 110-a may perform a read operation on the memory array 245 to retrieve data stored by the row of memory cells. However, during the read operation, the memory system 110-a may detect or experience (e.g., with or without detection) one or more errors in the data, which may cause the read operation to fail. Although the memory system 110-a may include error control circuitry (e.g., error detection circuitry, error correction circuitry, circuitry that may utilize error correction code, such as a Reed Solomon code, to detect or correct errors in the data), errors experienced by the memory system 110-a during the read operation may be too severe to correct (e.g., three or more symbols of the data may fail) using the error correction circuitry, which may result in a row failure.

In some examples, in response to a row failure or other error detection associated with the row of memory cells, the memory system 110-a may transmit a signal to the host system 105-a indicating that the read operation corresponding to the row of memory cells has failed. In some other examples, such an error may be detected at the host system 105-a based on data received from the memory system 110-a. In response to the detected row failure, the memory system 110-a may perform an operation associated with the row of memory cells. For example, the memory system 110-a may perform a row recovery operation on the row of memory cells. An example of a row repair operation may include a post package repair (PPR) operation. After initiating the PPR operation, the memory system 110-a may replace the row of memory cells with a spare row of memory cells. The memory system 110-a may retire the row of memory cells such that the row of memory cells may not be accessed in the future, but instead, the spare row of memory cells may be accessed.

Row failures at the memory array(s) 245 may not be instantaneous, and may occur after an accumulation of multiple errors over time. For example, failure of a row of memory cells may be indicated as a result of multiple single bit errors that occur over multiple read operations performed on the row of memory cells. Therefore, it may be beneficial for the system 200 to support health monitoring of memory rows such that row repair operations can be performed proactively on the memory rows before more significant row failures or access failures.

As described herein, the system 200 may implement a health monitoring algorithm to proactively repair failing rows of memory cells of the memory system 110-a. For example, one or both of the host system 105-a or the memory system 110-a may include a buffer 215 (e.g., a buffer 215-a, a buffer 215-b). At the memory system 110-a, the buffer 215-b may be located within the controller 240 of the memory system 110-a. At the host system 105-a, the buffer 215-a may be located within the controller 220 of the host system 105-a. In some examples, the host system 105-a may transmit a read command to the memory system 110-a to read a row of memory cells of the memory array 245. Based on (e.g., in response to) receiving the read command, the memory system 110-a may perform a read operation on the memory array 245 to obtain data from the memory array 245. In response to the read operation, the memory system 110-a (e.g., the controller 240, based on data read from the row of memory cells)) or the host system 105-a (e.g., the controller 220, based on data transmitted by the memory system 110-a) may detect one or more errors in the data (e.g., using error control circuitry).

According to a first technique, in response to detecting the one or more errors, the memory system 110-a may allocate (e.g., store, increment) a counter 225-b in the buffer 215-b and allocate the counter 225-b to track errors of the row of memory cells. Additionally, the memory system 110-a may adjust (or increment) a value of the counter 225-b based on the detected one or more errors. According to a second technique, the memory system 110-a may transmit signaling to the host system 105-a including an indication of the one or more detected errors (e.g., with or without the memory system 110-a itself detecting the error). Based on (e.g., in response to) receiving the signaling, the host system 105-a may store a counter 225-a in the buffer 215-a and allocate the counter 225-a to track errors of the row of memory cells. Additionally, the host system 105-a may adjust (or increment) a value of the counter 225-a based on the detected one or more errors.

In some examples, the value of the allocated counter 225 may represent a quantity of bits in the data stored at the row of memory cells that have failed (e.g., a quantity of bit failures of the row of memory cells). In such examples, based on identifying the detected one or more errors, the host system 105-a or the memory system 110-a may determine a quantity of bits affected by the one or more detected errors and increment the allocated counter 225 accordingly. As one example, the host system 105-a or the memory system 110-a may determine that the one or more detected errors include a single bit error and a double bit error. In such case, the host system 105-a or the memory system 110-a may determine a quantity of bits affected by the single bit error (e.g., one bit) and a quantity of bits affected by the double bit error (e.g., two bits), Additionally, the memory system 110-a or the host system 105-a may add the quantities to determine a total quantity of bits affected (e.g., three bits) and increase the value of the counter 225 by the total quantity of bits affected (e.g., increase the value of the counter 225 by a value of three). Examples of detected errors may include one or more single bit errors, one or more double bit errors, one or more sub-word line failures, or one or more sub-word line driver failures, each of which may be associated with a corresponding quantity of errors.

Based on adjusting the value of the counter 225, the memory system 110-a or the host system 105-a may compare the value of the counter 225 to a threshold. In some examples, the threshold may include a percentage of the total quantity of bits included in the data stored by the row of memory cells (e.g., a quantity of bits of the row, a quantity of memory cells of the row). For example, the threshold may be twenty percent of the total quantity of bits included in the data stored by the row of memory cells. If the value of the counter 225 exceeds or is equal to the threshold, the memory system 110-a may perform or the host system 105-a may instruct the memory system 110-a to perform one or more operations associated with the row of memory cells (e.g., PPR) and, as a result of performing the row operation(s), may deallocate the counter 225 from tracking errors of the row of memory cells. Alternatively, if the value of the counter 225 does not exceed or is not equal to the threshold, the memory system 110-a or the host system 105-a may not perform the one or more operations associated with the row of memory cells and, instead, the memory system 110-a or the host system 105-a may continue to track errors of the row of memory cells (e.g., until the value of the counter exceeds or is equal to the threshold). Thus, some examples of the techniques as described herein may support the memory system 110-a performing PPR on a row of memory cells without reporting a row failure to the host system 105-a.

In some examples, the memory system 110-a or the host system 105-a may track errors for multiple rows of memory cells. For example, the memory system 110-a or the host system 105-a may identify (e.g., while tracking errors of the row of memory cells) one or more errors in data stored by one or more second rows of memory cells of the memory array(s) 245. In response to identifying the one or more errors, the host system 105-a or the memory system 110-a may allocate respective second counter(s) 225 in the buffer 215 to track errors of the second row(s) of memory cells. Additionally, the host system 105-a or the memory system 110-a may adjust (e.g., increment, accumulate) the value of the second counter(s) 225 based on the identified one or more errors. Accordingly, the buffer 215 may be configured to store any quantity of one or more counters 225, each allocated for a respective row of memory cells of the memory array 245. In some examples, the quantity of allocated counters 225 stored in a buffer 215 may be less than a total quantity of memory rows of the memory array(s), which may be more efficient that preemptively allocating a counter 225 for every row of the memory array(s) 245.

In some examples, the memory system 110-a or the host system 105-a may not allocate a counter 225 in the buffer 215 to a particular single row of memory cells. Instead, the row of memory cells for which a counter 225 is allocated may change over time. For example, the memory system 110-a or the host system 105-a may initially allocate the counter 225 to track errors of a first row of memory cells. However, the value of the counter 225 may exceed the threshold and in response to the value of the counter 225 exceeding the threshold, the memory system 110-a or the host system 105-a may deallocate the counter 225 from tracking errors of the first row of memory cells such that the memory system 110-a or the host system 105-a may be allocate the counter 225 to track errors of a second, different row of memory cells of the memory array(s) 245 (e.g., based on detecting one or more errors in data stored by the different row of memory cells). Using the methods as described herein, the system 200 may monitor a health of memory rows of the memory array(s) 245 by accounting for their reliability over time, which may allow the system 200 to proactively employ row repair.

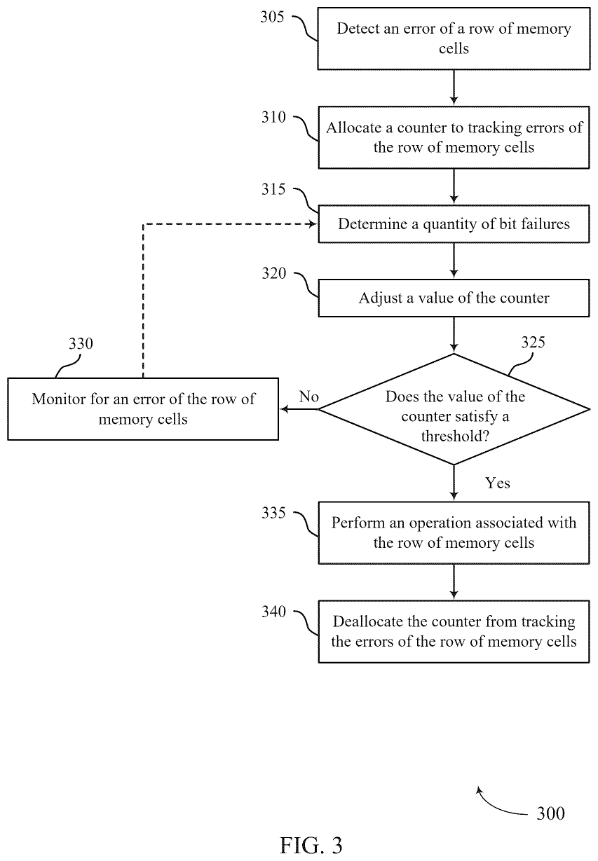

FIG. 3 shows an example of a process 300 that supports row error monitoring for memory systems in accordance with examples as disclosed herein. Operations of the process 300 may be implemented by aspects of a system 100 or a system 200. For example, one or more of the operations of 305 through 340 may be performed by a host system controller 120, a memory system controller 140, or a local controller 150, or a combination thereof. Additionally, or alternatively, one or more of the operations of 305 through 340 may be performed by a controller 220, or a controller 240, or a combination thereof.

At 305, the process 300 may include detecting (e.g., at a memory system 110, at a host system 105 coupled with a memory system 110) at least one error of a row of memory cells of a memory system 110. In some examples, the error may include a single bit error, a double bit error, a sub-word line failure, or a sub-word line driver failure.

At 310, the process 300 may include allocating a counter (e.g., a counter 225, a previously unallocated counter, at the memory system 110, at the host system 105) to tracking errors of the row of memory cells. In some examples, the counter may be allocated in a buffer of the system (e.g., a buffer 215, at the memory system 110, at the host system 105).

At 315, the process 300 may include determining (e.g., at the memory system 110, at the host system 105) a quantity of bit failures associated with the row of memory cells based on the detected error. In some examples, the quantity of bit failures may be equal to a quantity of bits stored by the row of memory cells that were affected by the detected error.

At 320, process 300 may include adjusting a value of the counter based on errors of the row of memory cells including the detected error. For example, the system (e.g., the memory system 110, the host system 105) may increase the value of the counter by the determined quantity of bit failures determined at 315. In some examples, the value of the counter may correspond to a cumulative quantity of bit failures associated with the row of memory cells.

At 325, the process 300 may include comparing (e.g., at the memory system 110, at the host system 105) the value of the counter with a threshold and determining whether the value of the counter satisfies (e.g., exceeds, is equal to, is greater than or equal to) the threshold. In some examples, the threshold may be equal to a percentage of a quantity of bits stored by the row of memory cells. If the value of the counter satisfies the threshold, the process 300 may proceed to 335. If the value of the counter does not satisfy the threshold, the process 300 may proceed to 330.

At 330, the process 300 may include monitoring (e.g., at the memory system 110, at the host system 105) for one or more additional errors of the row of memory cells and proceed to 315 if the system detects one or more additional errors of the row of memory cells.

At 335, the process 300 may include performing an operation associated with the row of memory cells (e.g., an operation on the row of memory cells at the memory system 110, an operation initiated at the host system 105). In some examples, performing the operation may include performing a PPR operation on the row of memory cells, which may involve repairing the row of memory cells, retiring the row of memory cells, or reallocating an address space to another row of memory cells, among other operations.

At 340, the process 300 may include deallocating the allocated counter (e.g., at the memory system 110, at the host system 105) from tracking errors of the row of memory cells (e.g., in response to the row operation of 335).

In some examples, a system (e.g., a memory system 110, a host system 105) may simultaneously track errors for multiple rows of memory cells. For example, the system may detect an error of a second row of memory cells, allocate a second counter to track errors of the second row of memory cells, and adjust a value of the second counter based on errors of the second row of memory cells including the detected error of the second row of memory cells. Accordingly, the system may store multiple counters (e.g., the counter allocated for tracking errors of the row of memory cells and the counter allocated for tracking errors of the second row of memory cells). In some examples, a quantity of counters stored in the buffer of the system may be less than a total quantity of rows of memory cells of the memory system, which may be a more efficient (e.g., more dynamic, more responsive) allocation than preemptively allocating a counter for every row of memory cells of the memory system 110 regardless of whether a given row is experiencing errors.

In some examples, after deallocating a counter from tracking errors of a row of memory cells, the system may allocate the counter for tracking errors of a different row of memory cells. For example, after deallocating the counter from tracking errors of the row of memory cells, the system may allocate the counter to tracking errors of a third row of memory cells based on detecting one or more errors of the third row of memory cells and adjust a value of the counter based on errors of the third row of memory cells including the detected one or more errors. Using these methods, the system may proactively fix row failures (e.g., apply row repair operations prior to row failure) which may increase the reliability of the system.

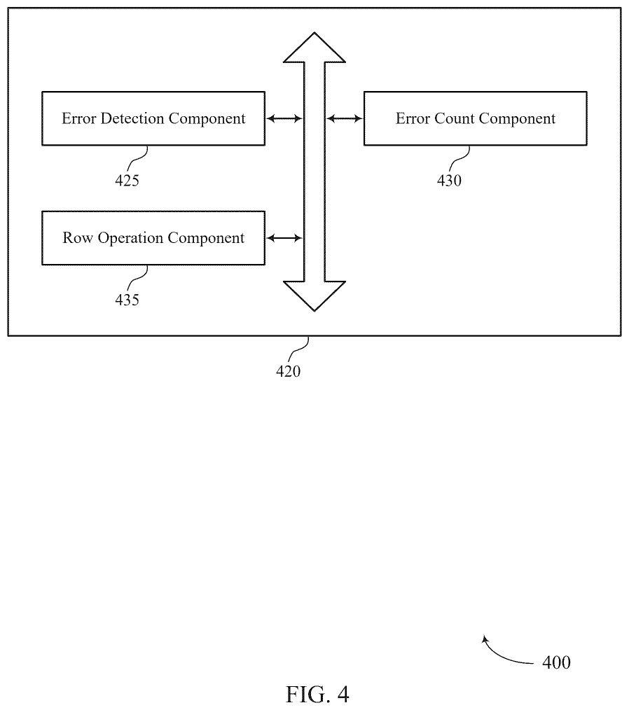

FIG. 4 shows a block diagram 400 of an electronic device 420 that supports row error monitoring for memory systems in accordance with examples as disclosed herein. The electronic device 420 may be an example of aspects of a memory system or a host system as described with reference to FIGS. 1 through 3, and may include processing circuitry (e.g., a host system controller 120, a memory system controller 140, or one or more local controllers 150, or a combination thereof) associated with accessing a memory system 110 (e.g., one or more memory devices 145). The electronic device 420, or various components thereof, may be an example of means for performing various aspects of row error monitoring for memory systems as described herein. For example, the electronic device 420 may include an error detection component 425, an error count component 430, a row operation component 435, or any combination thereof. Each of these components, or components of subcomponents thereof (e.g., one or more processors, one or more memories), may communicate, directly or indirectly, with one another (e.g., via one or more buses).

The electronic device 420 may support memory operations in accordance with examples as disclosed herein. The error detection component 425 may be configured as or otherwise support a means for detecting one or more errors of a row of memory cells of a memory system based on reading the row of memory cells. The error count component 430 may be configured as or otherwise support a means for allocating a counter (e.g., of the electronic device 420) to tracking errors of the row of memory cells based on detecting the one or more errors of the row of memory cells. In some examples, the error count component 430 may be configured as or otherwise support a means for adjusting a value of the allocated counter based on errors of the row of memory cells including the detected one or more errors. The row operation component 435 may be configured as or otherwise support a means for performing an operation associated with the row of memory cells based on the adjusted value of the allocated counter satisfying a threshold.

In some examples, to support performing the operation, the row operation component 435 may be configured as or otherwise support a means for performing a post package repair operation on the row of memory cells based on the adjusted value of the allocated counter satisfying a threshold. In some examples, to support performing the operation, the row operation component 435 may be configured as or otherwise support a means for retiring the row of memory cells based on the adjusted value of the allocated counter satisfying a threshold.

In some examples, the error count component 430 may be configured as or otherwise support a means for allocating a second counter (e.g., of the electronic device 420) to tracking errors of a second row of memory cells of the memory system based on detecting one or more errors of the second row of memory cells. In some examples, the error count component 430 may be configured as or otherwise support a means for adjusting a value of the allocated second counter based on errors of the second row of memory cells including the detected one or more errors of the second row of memory cells.

In some examples, the error count component 430 may be configured as or otherwise support a means for allocating the counter in a buffer (e.g., of the electronic device 420.

In some examples, the error count component 430 may be configured as or otherwise support a means for storing a plurality of counters including the counter in a buffer (e.g., of the electronic device 420), where a quantity of the plurality of counters is less than a total quantity of rows of memory cells of the memory system.

In some examples, the error count component 430 may be configured as or otherwise support a means for deallocating the allocated counter from tracking errors of the row of memory cells based on performing the operation.

In some examples, the error count component 430 may be configured as or otherwise support a means for allocating, after performing the operation, the counter to tracking errors of a third row of memory cells of the memory system based on detecting one or more errors of the third row of memory cells. In some examples, the error count component 430 may be configured as or otherwise support a means for adjusting the value of the allocated counter based on errors of the third row of memory cells including the detected one or more errors of the third row of memory cells. In some examples, the adjusted value of the counter corresponds to a cumulative quantity of bit failures associated with the row of memory cells.

In some examples, the one or more errors include one or more single bit errors, one or more double bit errors, one or more sub-word line failures, one or more sub-word line driver failures, or a combination thereof. In some examples, each error of the one or more errors corresponds to a respective quantity of bit failures of the row of memory cells.

In some examples, the row operation component 435 may be configured as or otherwise support a means for determining that the adjusted value of the allocated counter satisfies the threshold based on the adjusted value of the counter exceeding a percentage of a quantity of bits stored by the row of memory cells.

In some examples, the described functionality of the electronic device 420 (e.g., a host system 105, a memory system 110), or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the electronic device 420, or various components thereof, may be implemented at least in part by instructions (e.g., stored in memory, non-transitory computer-readable medium) executable by such at least one processor.

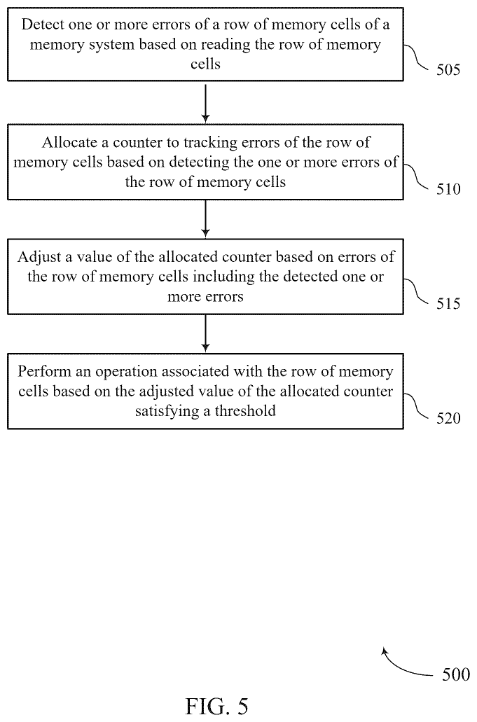

FIG. 5 shows a flowchart illustrating a method 500 that supports row error monitoring for memory systems in accordance with examples as disclosed herein. The operations of method 500 may be implemented by a host system or a memory system or its components as described herein. For example, the operations of method 500 may be performed by a host system or a memory system as described with reference to FIGS. 1 through 4. In some examples, a host system or a memory system may execute a set of instructions to control the functional elements of the device to perform the described functions. Additionally, or alternatively, the host system or the memory system may perform aspects of the described functions using special-purpose hardware.

At 505, the method may include detecting one or more errors of a row of memory cells of a memory system 110 (e.g., of a memory array 245, of a memory device 145) based on reading the row of memory cells. In some examples, aspects of the operations of 505 may be performed by an error detection component 425 as described with reference to FIG. 4.

At 510, the method may include allocating a counter (e.g., a counter 225, of the host system or memory system, of a controller 220, of a controller 240) to tracking errors of the row of memory cells based on detecting the one or more errors of the row of memory cells. In some examples, aspects of the operations of 510 may be performed by an error count component 430 as described with reference to FIG. 4.

At 515, the method may include adjusting a value of the allocated counter based on errors of the row of memory cells including the detected one or more errors. In some examples, aspects of the operations of 515 may be performed by an error count component 430 as described with reference to FIG. 4.

At 520, the method may include performing an operation associated with the row of memory cells based on the adjusted value of the allocated counter satisfying a threshold. In some examples, aspects of the operations of 520 may be performed by a row operation component 435 as described with reference to FIG. 4.

In some examples, an apparatus (e.g., an electronic device) as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for detecting one or more errors of a row of memory cells of a memory system based on reading the row of memory cells; allocating a counter (e.g., a counter 225, of a controller 220, of a controller 240) to tracking errors of the row of memory cells based on detecting the one or more errors of the row of memory cells; adjusting a value of the allocated counter based on errors of the row of memory cells including the detected one or more errors; and performing an operation associated with the row of memory cells based on the adjusted value of the allocated counter satisfying a threshold.
Aspect 2: The method, apparatus, or non-transitory computer-readable medium of aspect 1, where performing the operation includes operations, features, circuitry, logic, means, or instructions, or any combination thereof for performing a post package repair operation on the row of memory cells based on the adjusted value of the allocated counter satisfying a threshold.
Aspect 3: The method, apparatus, or non-transitory computer-readable medium of any of aspects 1 through 2, where performing the operation includes operations, features, circuitry, logic, means, or instructions, or any combination thereof for retiring the row of memory cells based on the adjusted value of the allocated counter satisfying a threshold.

Aspect 4: The method, apparatus, or non-transitory computer-readable medium of any of aspects 1 through 3, further including operations, features, circuitry, logic, means, or instructions, or any combination thereof for allocating a second counter to tracking errors of a second row of memory cells of the memory system based on detecting one or more errors of the second row of memory cells and adjusting a value of the allocated second counter based on errors of the second row of memory cells including the detected one or more errors of the second row of memory cells.
Aspect 5: The method, apparatus, or non-transitory computer-readable medium of any of aspects 1 through 4, further including operations, features, circuitry, logic, means, or instructions, or any combination thereof for allocating the counter in a buffer (e.g., a buffer 215).
Aspect 6: The method, apparatus, or non-transitory computer-readable medium of any of aspects 1 through 5, further including operations, features, circuitry, logic, means, or instructions, or any combination thereof for storing a plurality of counters including the counter in a buffer (e.g., a buffer 215), where a quantity of the plurality of counters is less than a total quantity of rows of memory cells of the memory system.
Aspect 7: The method, apparatus, or non-transitory computer-readable medium of any of aspects 1 through 6, further including operations, features, circuitry, logic, means, or instructions, or any combination thereof for deallocating the allocated counter from tracking errors of the row of memory cells based on performing the operation.
Aspect 8: The method, apparatus, or non-transitory computer-readable medium of any of aspects 1 through 7, further including operations, features, circuitry, logic, means, or instructions, or any combination thereof for allocating, after performing the operation, the counter to tracking errors of a third row of memory cells of the memory system based on detecting one or more errors of the third row of memory cells and adjusting the value of the allocated counter based on errors of the third row of memory cells including the detected one or more errors of the third row of memory cells.
Aspect 9: The method, apparatus, or non-transitory computer-readable medium of any of aspects 1 through 8, where the adjusted value of the counter corresponds to a cumulative quantity of bit failures associated with the row of memory cells.
Aspect 10: The method, apparatus, or non-transitory computer-readable medium of any of aspects 1 through 9, where the one or more errors include one or more single bit errors, one or more double bit errors, one or more sub-word line failures, one or more sub-word line driver failures, or a combination thereof and each error of the one or more errors corresponds to a respective quantity of bit failures of the row of memory cells.
Aspect 11: The method, apparatus, or non-transitory computer-readable medium of any of aspects 1 through 10, further including operations, features, circuitry, logic, means, or instructions, or any combination thereof for determining that the adjusted value of the allocated counter satisfies the threshold based on the adjusted value of the counter exceeding a percentage of a quantity of bits stored by the row of memory cells.
It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus for memory operations, comprising:
processing circuitry associated with accessing a memory system and configured to cause the apparatus to:
detect one or more errors of a row of memory cells of the memory system based on reading the row of memory cells;
allocate a counter of the apparatus to tracking errors of the row of memory cells based on detecting the one or more errors of the row of memory cells;
adjust a value of the allocated counter based on errors of the row of memory cells including the detected one or more errors; and
perform an operation associated with the row of memory cells based on the adjusted value of the allocated counter satisfying a threshold.

2. The apparatus of claim 1, wherein, to perform the operation, the processing circuitry is configured to cause the apparatus to:
perform a post package repair operation on the row of memory cells based on the adjusted value of the allocated counter satisfying a threshold.

3. The apparatus of claim 1, wherein, to perform the operation, the processing circuitry is configured to cause the apparatus to:
retire the row of memory cells based on the adjusted value of the allocated counter satisfying a threshold.

4. The apparatus of claim 1, wherein the processing circuitry is further configured to cause the apparatus to:
allocate a second counter of the apparatus to tracking errors of a second row of memory cells of the memory system based on detecting one or more errors of the second row of memory cells; and
adjust a value of the allocated second counter based on errors of the second row of memory cells including the detected one or more errors of the second row of memory cells.

5. The apparatus of claim 1, wherein the processing circuitry is further configured to cause the apparatus to:
allocate the counter in a buffer of the apparatus.

6. The apparatus of claim 1, wherein the processing circuitry is further configured to cause the apparatus to:
store a plurality of counters including the counter in a buffer of the apparatus, wherein a quantity of the plurality of counters is less than a total quantity of rows of memory cells of the memory system.

7. The apparatus of claim 1, wherein the processing circuitry is further configured to cause the apparatus to:
deallocate the allocated counter from tracking errors of the row of memory cells based on performing the operation.

8. The apparatus of claim 1, wherein the processing circuitry is further configured to cause the apparatus to:
allocate, after performing the operation, the counter to tracking errors of a third row of memory cells of the memory system based on detecting one or more errors of the third row of memory cells; and
adjust the value of the allocated counter based on errors of the third row of memory cells including the detected one or more errors of the third row of memory cells.

9. The apparatus of claim 1, wherein the adjusted value of the counter corresponds to a cumulative quantity of bit failures associated with the row of memory cells.

10. The apparatus of claim 1, wherein the one or more errors comprise one or more single bit errors, one or more double bit errors, one or more sub-word line failures, one or more sub-word line driver failures, or a combination thereof, and each error of the one or more errors corresponds to a respective quantity of bit failures of the row of memory cells.

11. The apparatus of claim 1, wherein the processing circuitry is further configured to cause the apparatus to:
determine that the adjusted value of the allocated counter satisfies the threshold based on the adjusted value of the counter exceeding a percentage of a quantity of bits stored by the row of memory cells.

12. A method for memory operations, comprising:
detecting one or more errors of a row of memory cells of a memory system based on reading the row of memory cells;
allocating a counter to tracking errors of the row of memory cells based on detecting the one or more errors of the row of memory cells;
adjusting a value of the allocated counter based on errors of the row of memory cells including the detected one or more errors; and
performing an operation associated with the row of memory cells based on the adjusted value of the allocated counter satisfying a threshold.

13. The method of claim 12, wherein performing the operation comprises:
performing a post package repair operation on the row of memory cells based on the adjusted value of the allocated counter satisfying a threshold.

14. The method of claim 12, wherein performing the operation comprises:
retiring the row of memory cells based on the adjusted value of the allocated counter satisfying a threshold.

15. The method of claim 12, further comprising:
allocating a second counter to tracking errors of a second row of memory cells of the memory system based on detecting one or more errors of the second row of memory cells; and
adjusting a value of the allocated second counter based on errors of the second row of memory cells including the detected one or more errors of the second row of memory cells.

16. The method of claim 12, further comprising:
storing a plurality of counters including the counter in a buffer, wherein a quantity of the plurality of counters is less than a total quantity of rows of memory cells of the memory system.

17. The method of claim 12, further comprising:
deallocating the allocated counter from tracking errors of the row of memory cells based on performing the operation.

18. The method of claim 12, further comprising:
allocating, after performing the operation, the counter to tracking errors of a third row of memory cells of the memory system based on detecting one or more errors of the third row of memory cells; and
adjusting the value of the allocated counter based on errors of the third row of memory cells including the detected one or more errors of the third row of memory cells.

19. The method of claim 12, further comprising:
determining that the adjusted value of the allocated counter satisfies the threshold based on the adjusted value of the counter exceeding a percentage of a quantity of bits stored by the row of memory cells.

20. The method of claim 12, performed at the memory system.

21. The method of claim 12, performed at a host system coupled with the memory system.

22. A non-transitory computer-readable medium storing code comprising instructions which, when executed by processing circuitry of an electronic device, cause the electronic device to:
detect one or more errors of a row of memory cells of a memory system based on reading the row of memory cells;
allocate a counter of the electronic device to tracking errors of the row of memory cells based on detecting the one or more errors of the row of memory cells;
adjust a value of the allocated counter based on errors of the row of memory cells including the detected one or more errors; and
perform an operation associated with the row of memory cells based on the adjusted value of the allocated counter satisfying a threshold.
